(19) United States
(12) Patent Application Publication
(10) Pub. No.: US 2025/0306094 A1
(43) Pub. Date: Oct. 2, 2025

(54) ELECTRICAL CONNECTION TESTING

(71) Applicant: ASML Netherlands B.V., Veldhoven (NL)

(72) Inventors: Benoit Herve GUARY, Eindhoven (NL); Etienne Pierre L. DE POORTERE, Brussels (BE); Thomas Jarik HUISMAN, Eindhoven (NL); Mathijs Wouter Henk GARMING, Vught (NL)

(73) Assignee: ASML Netherlands B.V., Veldhoven (NL)

(21) Appl. No.: 19/182,287

(22) Filed: Apr. 17, 2025

Related U.S. Application Data
(63) Continuation of application No. PCT/EP2023/078718, filed on Oct. 16, 2023.

(30) Foreign Application Priority Data
Oct. 17, 2022 (EP) 22201818.6

(51) Int. Cl. G01R 31/307; G01R 1/07; G01R 31/52

(52) U.S. Cl. CPC G01R 31/307; G01R 1/07; G01R 31/52

(57) ABSTRACT

A method for testing an array of devices, each having an electrical connection between two electrodes controllable by a signal applied to a control element, comprises: applying a reference electric potential to a first electrode of the two electrodes of each device; directing a charged particle beam onto a second electrode of the two electrodes of each device; varying a signal applied to the control element of each device; and monitoring, for each signal applied, signal charged particles from the second electrode of each device.

### CROSS-REFERENCE TO RELATED APPLICATIONS

This application claims priority of International application PCT/EP2023/078718, filed on 16 Oct. 2023, which claims priority of EP application 22201818.6, filed on 17 Oct. 2022. These applications are incorporated herein by reference in its entireties.

### TECHNICAL FIELD

The embodiments provided herein disclose a method for testing an array of devices, a charged particle-optical apparatus for testing an array of devices, substrate comprising in a test region a two-dimensional array of logic transistors and a non-transitory computer readable medium.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, and their structures continue to become more complex, accuracy and throughput in defect detection and inspection become more important. The overall image quality depends on a combination of high secondary-electron and backscattered-electron signal detection efficiencies, among others. Backscattered electrons have higher emission energy to escape from deeper layers of a sample, and therefore, their detection may be desirable for imaging of complex structures such as buried layers, nodes, high-aspect-ratio trenches or holes of 3D NAND devices. For applications such as overlay metrology, it may be desirable to obtain high quality imaging and efficient collection of surface information from secondary electrons and buried layer information from backscattered electrons, simultaneously, highlighting a need for using multiple electron detectors in a SEM. Although multiple electron detectors in various structural arrangements may be used to maximize collection and detection efficiencies of secondary and backscattered electrons individually, the combined detection efficiencies remain low, and therefore, the image quality achieved may be inadequate for high accuracy and high throughput defect inspection and metrology of two-dimensional and three-dimensional structures.

### SUMMARY

Some embodiments of the present disclosure provide a method for testing an array of devices each having an electrical connection between two electrodes controllable by a signal applied to a control element, the method comprising: applying a reference electric potential to a first electrode of the two electrodes of each device; directing a charged particle beam onto a second electrode of the two electrodes of each device; varying a signal applied to the control element of each device; and monitoring, for each signal applied, signal charged particles from the second electrode of each device.

Some embodiments of the present disclosure provide a charged particle-optical apparatus for testing an array of devices each having an electrical connection between two electrodes controllable by a signal applied to a control element, the electron-optical apparatus comprising: a reference voltage supply configured to supply a reference electric potential to a first electrode of the two electrodes of each device; a charged particle-optical device configured to direct a charged particle beam onto a second electrode of the two electrodes of each device; a signal supply configured to vary a signal applied to the control element of each device; and a detector for monitoring, for each signal applied, signal charged particles from the second electrode of each device.

Some embodiments of the present disclosure provide a substrate comprising in a test region an arrangement of devices each having an electrical connection between a source electrode and a drain electrode controllable by an electric potential applied to a gate electrode, wherein the source electrodes or the drain electrodes are connected to a common reference contact and whichever of the source electrodes and the drain electrodes are not connected to the common reference contact are electrically coupled to respective electrode contacts exposed at a surface of the substrate.

Some embodiments of the present disclosure provide a non-transitory computer readable medium that stores instructions for a processor of a controller to carry out a method for testing an array of devices each having an electrical connection between two electrodes controllable by a signal applied to a control element, the method comprising: controlling application of a reference electric potential to a first electrode of the two electrodes of each device; controlling direction of a charged particle beam onto a second electrode of the two electrodes of each device; controlling variation of a signal applied to the control element of each device; and controlling monitoring, for each signal applied, of signal charged particles from the second electrode of each device.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

The above and other aspects of the present disclosure will become more apparent from the description of exemplary embodiments, taken in conjunction with the accompanying drawings in which:

FIG. 1 is a schematic diagram illustrating an exemplary electron beam inspection (EBI) system, consistent with embodiments of the present disclosure.

FIG. 2A, FIG. 2B, and FIG. 2C are schematic diagrams illustrating exemplary electron beam tools, consistent with embodiments of the present disclosure that may be a part of the exemplary electron beam inspection system of FIG. 1.

FIG. 3 is a diagram of an array of logic transistors for testing electrical connections.

FIG. 4 is a graph showing the relationship between a gate voltage and detected signal electrons from drain electrodes of logic transistors.

FIG. 5 is a diagram of an array of DRAM structures for testing electrical connections.

FIG. 6 is a diagram of an array of devices under test (DUTs), with varying structures across the array, for testing electrical connections.

FIG. 7 is a diagram of an arrangement of logic transistors for testing electrical connections.

FIG. 8 is a diagram showing how the logic transistors of FIG. 7 are electrically connected to the surface of the substrate.

FIG. 9 is a diagram of an alternative arrangement of devices such as logic transistors.

FIG. 10 is a diagram of an array of DUTs of different types.

FIG. 11 is a diagram showing an alternative arrangement of logic transistors for testing electrical connections.

FIG. 12 is a diagram showing a generic implementation of device measurement with a charged particle beam.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Characterization of transistors in the manufacturing process can be done with electrical tests performed by physical probes and metal pads. These test structures require large areas. Realistically, only a small number of transistors of a given type can be tested per substrate. Embodiments of the present disclosure allow characterization of transistors based on scanning a large number of transistors with an SEM, for example, and detecting the secondary-electron and backscattered-electron signal. The detected signal indicates the extent to which each transistor is switched on. This allows a much larger number of transistors (or other devices with a switchable current flow) to be tested.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

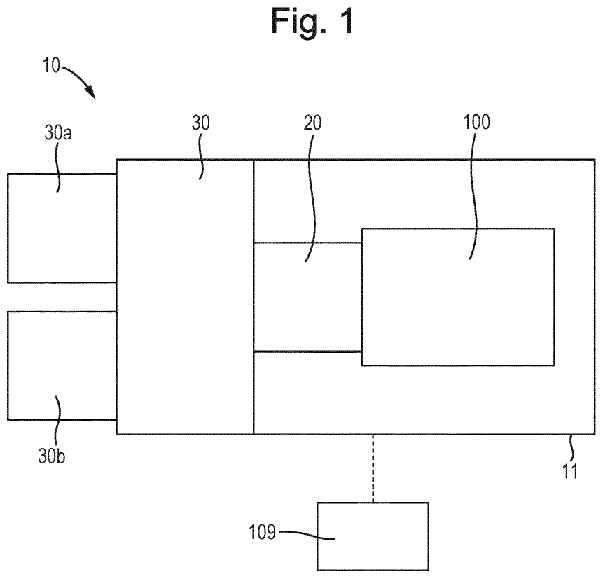

Reference is now made to FIG. 1, which illustrates an exemplary EBI system 10 that may include a detector, consistent with embodiments of the present disclosure. EBI system 10 may be used for imaging. As shown in FIG. 1, EBI system 10 includes a main chamber 11 a load/lock chamber 20, an electron beam tool 100, and an equipment front end module (EFEM) 30. Electron beam tool 100 is located within main chamber 11. EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be inspected (wafers and samples may be collectively referred to as “samples” herein).

One or more robotic arms (not shown) in EFEM 30 may transport the wafers to load/lock chamber 20. Load/lock chamber 20 is connected to a load/lock vacuum pump system (not shown) which removes gas molecules in load/lock chamber 20 to reach a first pressure below the atmospheric pressure. After reaching the first pressure, one or more robotic arms (not shown) may transport the wafer from load/lock chamber 20 to main chamber 11. Main chamber 11 is connected to a main chamber vacuum pump system (not shown) which removes gas molecules in main chamber 11 to reach a second pressure below the first pressure. After reaching the second pressure, the wafer is subject to inspection by electron beam tool 100. Electron beam tool 100 may be a single-beam system or a multi-beam system. A controller 109 is electronically connected to electron beam tool 100 and may be electronically connected to other components as well. Controller 109 may be a computer configured to execute various controls of EBI system 10. While controller 109 is shown in FIG. 1 as being outside of the structure that includes main chamber 11, load/lock chamber 20, and EFEM 30, it is appreciated that controller 109 can be part of the structure.

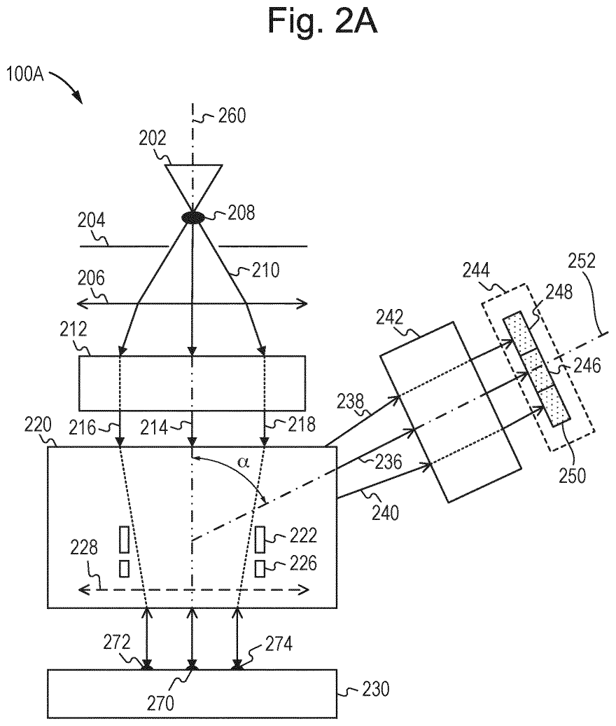

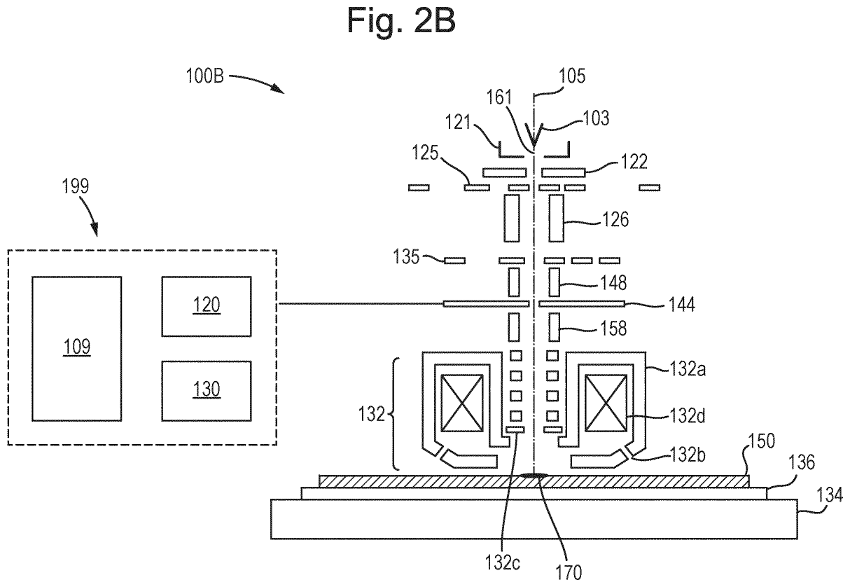

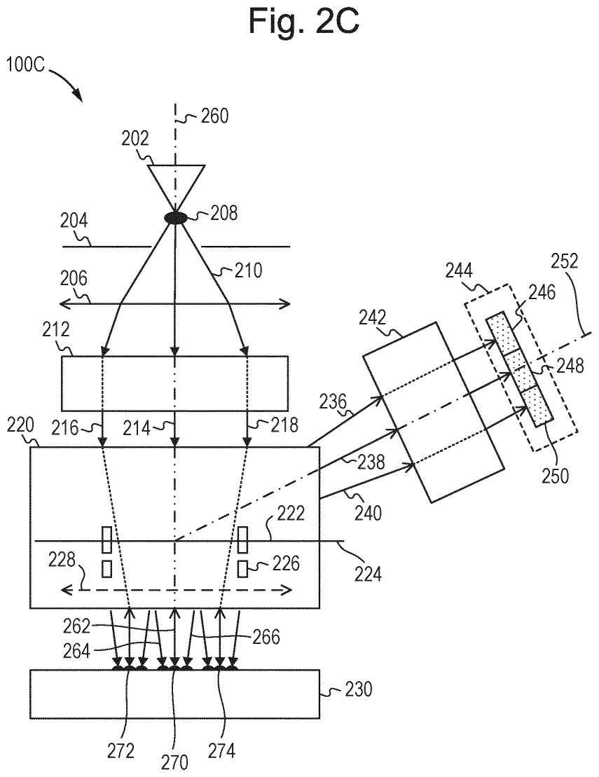

FIG. 2A illustrates a charged particle beam apparatus in which an inspection system may comprise a multi-beam inspection tool that uses multiple primary electron beamlets to simultaneously scan multiple locations on a sample.

As shown in FIG. 2A, an electron beam tool 100A (also referred to herein as an electron beam apparatus 100A or an electron-optical device) may comprise an electron source 202, a gun aperture 204, a condenser lens 206, a primary electron beam 210 emitted from electron source 202, a source conversion unit 212, a plurality of beamlets 214, 216, and 218 of primary electron beam 210, a primary projection optical system 220, a wafer stage (not shown in FIG. 2A), multiple secondary electron beams 236, 238, and 240, a secondary optical system 242, and an electron detection device 244. Electron source 202 may generate primary particles, such as electrons of primary electron beam 210. A controller, image processing system, and the like may be coupled to electron detection device 244. Primary projection optical system 220 may comprise a beam separator 222, deflection scanning unit 226, and objective lens 228. Electron detection device 244 may comprise detection sub-regions 246, 248, and 250.

Electron source 202, gun aperture 204, condenser lens 206, source conversion unit 212, beam separator 222, deflection scanning unit 226, and objective lens 228 may be aligned with a primary optical axis 260 of electron beam apparatus 100A. Secondary optical system 242 and electron detection device 244 may be aligned with a secondary optical axis 252 of electron beam apparatus 100A.

Electron source 202 may comprise a cathode, an extractor or an anode, wherein primary electrons can be emitted from the cathode and extracted or accelerated to form a primary electron beam 210 with a crossover (virtual or real) 208. Primary electron beam 210 can be visualized as being emitted from crossover 208. Gun aperture 204 may block off peripheral electrons of primary electron beam 210 to reduce size of probe spots 270, 272, and 274.

Source conversion unit 212 may comprise an array of image-forming elements (not shown in FIG. 2A) and an array of beam-limit apertures (not shown in FIG. 2A). An example of source conversion unit 212 may be found in U.S. Pat. No. 9,691,586; U.S. Publication No. 2017/0025243; and International Application No. PCT/EP2017/084429, all of which are incorporated by reference in their entireties. The array of image-forming elements may comprise an array of micro-deflectors or micro-lenses. The array of image-forming elements may form a plurality of parallel images (virtual or real) of crossover 208 with a plurality of beamlets 214, 216, and 218 of primary electron beam 210. The array of beam-limit apertures may limit the plurality of beamlets 214, 216, and 218.

Condenser lens 206 may focus primary electron beam 210. The electric currents of beamlets 214, 216, and 218 downstream of source conversion unit 212 may be varied by adjusting the focusing power of condenser lens 206 or by changing the radial sizes of the corresponding beam-limit apertures within the array of beam-limit apertures. Condenser lens 206 may be a moveable condenser lens that may be configured so that the position of its first principle plane is movable. The movable condenser lens may be configured to be magnetic, which may result in off-axis beamlets 216 and 218 landing on the beamlet-limit apertures with rotation angles. The rotation angles change with the focusing power and the position of the first principal plane of the movable condenser lens. In some embodiments, the moveable condenser lens may be a moveable anti-rotation condenser lens, which involves an anti-rotation lens with a movable first principal plane. A moveable condenser lens is further described in U.S. Publication No. 2017/0025241, which is incorporated by reference in its entirety.

Objective lens 228 may focus beamlets 214, 216, and 218 onto a wafer 230 (i.e. a sample) for inspection and may form a plurality of probe spots 270, 272, and 274 on the surface of wafer 230.

Beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. Beam separator 222 may separate secondary electron beams 236, 238, and 240 from beamlets 214, 216, and 218 and direct secondary electron beams 236, 238, and 240 towards secondary optical system 242.

Deflection scanning unit 226 may deflect beamlets 214, 216, and 218 to scan probe spots 270, 272, and 274 over a surface area of wafer 230. In response to incidence of beamlets 214, 216, and 218 at probe spots 270, 272, and 274, secondary electron beams 236, 238, and 240 may be emitted from wafer 230. Secondary electron beams 236, 238, and 240 may comprise electrons with a distribution of energies including secondary electrons and backscattered electrons. Secondary optical system 242 may focus secondary electron beams 236, 238, and 240 onto detection sub-regions 246, 248, and 250 of electron detection device 244. Detection sub-regions 246, 248, and 250 may be configured to detect corresponding secondary electron beams 236, 238, and 240 and generate corresponding signals used to reconstruct an image of surface area of wafer 230.

Although FIG. 2A shows an example of electron beam tool 100 as a multi-beam tool that uses a plurality of beamlets, embodiments of the present disclosure are not so limited. For example, electron beam tool 100 may also be a single-beam tool that uses only one primary electron beam to scan one location on a wafer at a time.

As shown in FIG. 2B, an electron beam tool 100B (also referred to herein as electron beam apparatus 100B) may be a single-beam inspection tool that is used in EBI system 10. Electron beam apparatus 100B includes an electron-optical device configured to project electrons towards a sample location (i.e. where the wafer is) and a wafer holder 136 supported by motorized stage 134 to hold a wafer 150 (i.e. a sample) to be inspected. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In an imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered primary particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of electron beam tool 100B through a medium such as an electrical conductor, optical fiber cable, portable storage media, IR, Bluetooth, Internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 158. In some embodiments, the quadrupole lenses are used for controlling the electron beam. For example, first quadrupole lens 148 can be controlled to adjust the beam current and second quadrupole lens 158 can be controlled to adjust the beam spot size and beam shape.

FIG. 2B illustrates a charged particle beam apparatus in which an inspection system may use a single primary beam that may be configured to generate secondary electrons by interacting with wafer 150. Detector 144 may be placed along optical axis 105, as in the example shown in FIG. 2B. The primary electron beam may be configured to travel along optical axis 105. Accordingly, detector 144 may include a hole at its center so that the primary electron beam may pass through to reach wafer 150. However, some embodiments may use a detector placed off-axis relative to the optical axis along which the primary electron beam travels. For example, as in the example shown in FIG. 2A, beam separator 222 may be provided to direct secondary electron beams toward a detector placed off-axis. Beam separator 222 may be configured to divert secondary electron beams by an angle α.

Another example of a charged particle beam apparatus will now be discussed with reference to FIG. 2C. Electron beam tool 100C (also referred to herein as an electron beam apparatus 100C or an electron-optical device) may be an example of electron beam tool 100 and may be similar to electron beam tool 100A shown in FIG. 2A.

As shown in FIG. 2C, beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. For a dispersion plane 224 of beam separator 222, FIG. 2C shows dispersion of beamlet 214 with nominal energy V0 and an energy spread ΔV into beamlet portions 262 corresponding to energy V0, beamlet portion 264 corresponding to energy V0+ΔV/2, and beamlet portion 266 corresponding to energy V0−ΔV/2. The total force exerted by beam separator 222 on an electron of secondary electron beams 236, 238, and 240 can be non-zero. Beam separator 222 may separate secondary electron beams 236, 238, and 240 from beamlets 214, 216, and 218 and direct secondary electron beams 236, 238, and 240 towards secondary optical system 242.

A semiconductor electron detector (sometimes called a “PIN detector”) may be used in apparatus 100 in EBI system 10. EBI system 10 may be a high-speed wafer imaging SEM including an image processor. An electron beam generated by EBI system 10 may irradiate the surface of a sample or may penetrate the sample. EBI system 10 may be used to image a sample surface or structures under the surface, such as for analyzing layer alignment. In some embodiments, EBI system 10 may detect and report process defects relating to manufacturing semiconductor wafers by, for example, comparing SEM images against device layout patterns, or SEM images of identical patterns at other locations on the wafer under inspection. A PIN detector may include a silicon PIN diode that may operate with negative bias. A PIN detector may be configured so that incoming electrons generate a relatively large and distinct detection signal. In some embodiments, a PIN detector may be configured so that an incoming electron may generate a number of electron-hole pairs while a photon may generate just one electron-hole pair. A PIN detector used for electron counting may have numerous differences as compared to a photodiode used for photon detection, as shall be discussed as follows.

In some embodiments, the detector (e.g. the electron detection device 244 shown in FIG. 2A or FIG. 2C or the detector 144 shown in FIG. 2B) comprises a plurality of detector elements (e.g. detection sub-regions 246, 248, and 250). The detector elements may be connected to one or more circuit layers. A circuit layer of the detector may comprise circuitry having amplification and/or digitation functions, e.g. it may comprise an amplification circuit. A circuit layer may comprise one or more trans impedance amplifiers (TIAs) and one or more ADCs. A detector element and an associated feedback resistor may be connected to the TIA and ADC. One or more digital signal lines may be connected from the ADC for transferring digital signals, e.g. to the image acquirer 120 shown in FIG. 2B.

In some embodiments, a detector may communicate with a controller that controls a charged particle beam system. The controller may instruct components of the charged particle beam system to perform various functions, such as controlling a charged particle source to generate a charged particle beam and controlling a deflector to scan the charged particle beam. The controller may also perform various other functions such as adjusting a sampling rate of a detector, resetting a sensing element, or performing image processing. In some embodiments, the controller is configured to control settings of the ADCs. The controller may comprise a storage that is a storage medium such as a hard disk, random access memory (RAM), other types of computer readable memory, and the like. The storage may be used for saving scanned raw image data as original images, and post-processed images. A non-transitory computer readable medium may be provided that stores instructions for a processor of controller 109 to carry out charged particle beam detection, sampling period determination, image processing, or other functions and methods consistent with the present disclosure. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a ROM, a PROM, and EPROM, a FLASH-EPROM or any other flash memory, NVRAM, a cache, a register, any other memory chip or cartridge, and networked versions of the same.

Block diagrams in the figures may illustrate the architecture, functionality, and operation of possible implementations of systems, methods, and computer hardware/software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

A method is disclosed for testing electrical connections. In some embodiments, the method is for characterising devices, for example transistors, on a substrate. Characterisation of a device may comprise determining one or more properties of the device. For example, when the device is a transistor, then the transistor may be characterised by one or more of its threshold voltage (on/off gate voltage), its leakage current at zero gate voltage and its sub-threshold IV slope (which determines how sharp the on/off transition is).

Embodiments of the method are described below primarily in the context of testing logic transistors, i.e. transistors that are used in logic circuits. Such logic transistors may be for binary purposes or may be for analogue applications. However, the method may be applied to testing other devices, particularly devices that have an electrical connection between two electrodes controllable by a signal applied to a control element (e.g. the gate electrode of a transistor). For example, the devices may be DRAM structures or photodiodes.

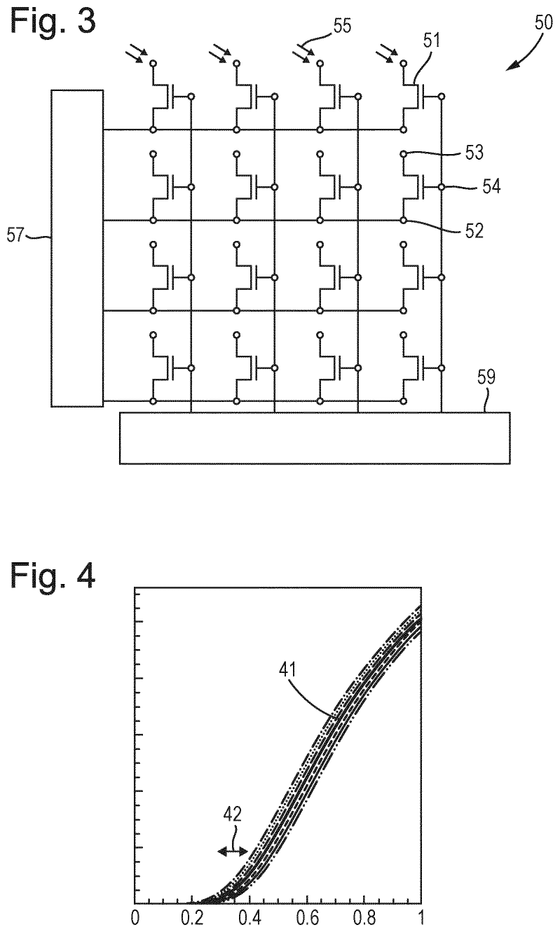

FIG. 3 schematically shows an array 50 of devices. In the example shown in FIG. 3, the devices are transistors 51. As shown in FIG. 3, in some embodiments, the array 50 is a two-dimensional array. In some embodiments, the transistors 51 are arranged in a regular pattern to form the array 50. In some embodiments, the transistors 51 are arranged in columns and rows of a grid in the array 50. It is not essential for the transistors 51 to be arranged in a regular pattern. The transistors 51 may be arranged irregularly. A regular pattern may make it easier to provide a higher density of transistors 51 in the array 50.

In some embodiments, the array 50 is a test structure for use when characterising the transistors 51. The test structure may not be used for functional parts of the substrate (e.g. functional parts of ICs). In some embodiments, the test structure is located in a scribe lane of the substrate. The test structure may be cut away when the chips are cut from the substrate.

In some embodiments, the transistors are formed in a particularly dense pattern. For example, in some embodiments, the transistors 51 are arranged at a pitch of at most 500 nm, optionally at most 200 nm, optionally at most 100 nm and optionally at most 50 nm. In some embodiments, the pitch is applicable to both the rows and columns of the grid of the array 50.

In some embodiments, all of the transistors 51 within the array 50 are of the same type. This means that all of the transistors 51 are manufactured with the same intended characteristics. For example, the transistors 51 may be designed to have the same threshold voltage as each other. Of course, there may be some variation in the actual properties (characteristics) of the transistors 51. It is desirable to test the array 50 of transistors 51 in order to determine characteristics of the actual transistors 51. For example, it may be determined what the average (e.g. mean) value of the voltage threshold and/or what the spread (e.g. standard deviation) of the threshold voltage is across the transistors 51 of the array 50.

As shown in FIG. 3, in some embodiments, each device comprises two electrodes between which an electrical connection may be made. In the example of transistors 51, the two electrodes may be the source electrode 52 and the drain electrode 53. When the transistor is switched on, a substantial or significant current may flow between the source electrode 52 and the drain electrode 53. When the transistor 51 is switched off, a sufficiently low current (or no current) may flow between the source electrode 52 and the drain electrode 53.

In some embodiments, the method comprises applying a reference electric potential to a first electrode of the two electrode 52, 53 of each device. For example, in the arrangement shown in FIG. 3, a reference electric potential is applied to the source electrode 52 of each transistor 51. In some embodiments, the reference electric potential may be applied to the drain electrode 53 of each transistor 51.

As shown in FIG. 3, in some embodiments, the first electrode (e.g. source electrode 52) of the transistors 51 are connected to a common reference potential so as to apply the reference electric potential. For example, all of the source electrodes 52 may be electrically connected to a common reference contact 57. The common reference contact 57 may be a terminal such as a pad. The voltage of the common reference contact 57 may be controlled, thereby controlling the reference electric potential applied to the source electrodes 52 of the transistors 51. By connecting the transistors 51 to a common reference potential, it may be easier to apply the reference electric potential to each transistor 51. By providing a single common reference contact 57, the space taken up by the overall test structure may be reduced.

In some embodiments, the reference electric potential is ground. For example, the ground may be a reference ground potential for an electron-optical apparatus such as the electron beam tool 100. Alternatively, a different reference electric potential may be used.

In some embodiments, the method comprises directing (e.g. projecting) a charged particle beam (e.g. an electron beam 55) onto a second electrode of the two electrodes of each device (e.g. transistor 51). The second electrode is the electrode that does not have the reference electric potential applied to it. In the context of transistors 51, the second electrode is one of the source electrode 52 and the drain electrode 53. In the example shown in FIG. 3, the second electrode is the drain electrode 53. Alternatively, the reference electric potential may be applied to the drain electrode 53 and the charged particle beam may be directed onto the source electrode 52.

In some embodiments, the electron beam is projected by an electron-optical device of an electron-optical apparatus (e.g. the electron beam tool 100). In some embodiments, the electron beam is projected onto all of the drain electrode 52 simultaneously. Alternatively, the electron beam may be scanned across the array 50 so as to project the electron beam onto the drain electrodes 53 sequentially.

In some embodiments, the controller 109 is configured to control the landing energy of the electron beam. The landing energy of the electron beam is the energy of the electrons at the sample location. In some embodiments, the controller 109 is configured to control the landing energy of the electron beam dependent on the type of transistors 51 within the array 50.

For example, when the transistors 51 are PMOS transistors, then the landing energy may be controlled to be at least 1 keV, optionally at least 2 keV, optionally at least 5 keV and optionally at least 10 keV. Such a landing energy may result in negative charging for PMOS transistors such that the pn junction below the irradiated drain electrode 53 is reverse biased. The reverse bias means that the electrons from the beam do not flow from the exposed drain electrode 53 to the silicon right below. Instead, the charges can only flow through the channel if the channel is open, or they accumulate at the drain electrode 53 if the channel is closed.

When the transistors 51 are NMOS transistors, then the controller 109 may control the landing energy to be at most 1 keV and optionally at most 500 eV and/or to be at least 100 eV, optionally at least 200 eV and optionally at least 500 eV. Such a landing energy may result in positive charging for NMOS transistors such that the pn junction below the irradiated drain electrode 53 is reverse biased.

In some embodiments, the method comprises varying a signal applied to the control element of each device (e.g. transistor 51). In the example of transistors 51 as the devices, the control element may be the gate electrode 54 of the transistor 51. The signal may be an electric potential. When a voltage above a threshold voltage is applied to the gate electrode 54, a substantial or significant current may flow between the source electrode 52 and the drain electrode 53. When a voltage below the threshold voltage is applied to the gate electrode 54, then no current may flow between the source electrode 52 and the drain electrode 53.

As shown in FIG. 3, in some embodiments, the control element of a plurality of the devices are connected to a common control electrode 59 so as to apply the varying electric potential. FIG. 3 shows all of the gate electrodes 54 of the transistors 51 connected electrically to the common control electrode 59. By providing a common control electrode 59, a known electric potential can be applied to the gate electrode 54 across the transistors 51 of the array 50. It can be easier to apply and vary the electric potential to the gate electrodes 54. By providing a common control electrode 59 for a plurality of the transistors 51, the total amount of space taken up by the testing structure may be reduced. In particular, it may not be necessary to provide a separate pad to apply a gate voltage to each transistor individually.

In some embodiments, the signal applied to the control element of each device (e.g. transistor 51) is gradually increased or decreased. For example, when the signal is an electric potential, the electric potential applied to the control elements may be gradually increased. In some embodiments, the signal is varied by sweeping the signal through a range. In some embodiments, the lower limit of the range is below the threshold signal of the devices such that each device is switched off and the high effective resistance of the transistor will yield a dark voltage contrast signal. A transistor for which the threshold voltage is lower than the applied gate voltage will give a voltage contrast signal with a first intensity, while a transistor for which the threshold voltage is higher than the applied gate voltage will give a voltage contrast signal with a second intensity, the second voltage contrast signal being weaker in intensity than the first voltage contrast signal. It is to be noted that the transistor current decreases exponentially when the applied gate voltage is lower than the threshold voltage, and the voltage contrast signal, which depends on the current through the transistor, therefore also strongly decreases as the applied gate voltage falls below the threshold voltage. In some embodiments, the upper limit of the range is above the signal threshold of the devices such that the devices are switched on and current flows between the two electrodes. As the signal is gradually increased, the device at the lowest threshold signal turns on. This may be detected as described in more detail below. As the signal is increased, more and more of the devices turn on. At the upper end of the range all of the devices are switched on. Of course, there may be one or more defective devices that can never be switched on.

In some embodiments, the method comprises monitoring, for each signal applied, signal charged particles (e.g. signal electrons) from the second electrode of each device. For example, when one signal (e.g. a particular electric potential) is applied to the control element (e.g. the gate electrode 54) of each device (e.g. transistor 51), then the detector 144 of the electron beam tool 100 detects signal electrons such as backscattered electrons and secondary electrons from each transistor 51. The detected signal electron data may be recorded for the given signal applied to the control elements of the devices. The signal applied to the control elements of the devices may then be changed (e.g. incrementally increased) and the signal electrons resulting from the electron beam projected onto the drain electrodes 53 may be monitored for the new applied signal. This monitoring step may be performed for each varied signal in turn. As a result, for each device in the array 50, signal electrons are detected for the given electric potential applied to the gate electrode 54.

FIG. 4 is a graph showing the relationship between the electric potential applied to the gate electrode 54 and the current of signal electrons detected as coming from that transistor 51. In FIG. 4, the X-axis represents the electric potential applied to the gate electrode 54 for a given transistor 51. The Y-axis represents the current of signal electrons detected from that transistor 51. This may also be referred to as the voltage contrast signal. FIG. 4 shows a plurality of curves 41 of signal electrons versus gate voltage. Each curve 41 may correspond to a respective transistor 51 of the array 50.

As shown in FIG. 4, the curves 41 may generally have a similar form to each other. However, there is a spread of curves. It is desirable to measure the extent to which the curves spread. This may be an indication of the manufacturing tolerance of parameters of the transistors 51 of a given type.

In some embodiments, the electron beam 55 is projected onto a via or contact metal associated with the transistor 51. In some embodiments, the electron beam 55 induces current that enters the drain electrode 53 of each transistor 51 through the exposed via or contact metal. The current of signal electrons from each via or contact metal depends on the threshold voltage of the associated transistor 51 and on the electric potential applied to the gate electrode 54. The threshold voltage of the transistors 51 may vary across the array 50, even if nominally all of the transistors 51 are of the same type (e.g. have the same intended threshold voltage). As shown in FIG. 4, the output may be a family of curves 41 showing the voltage contrast signal of each transistor 51 plotted against the gate voltage. This plot may be enough to measure a distribution of the threshold voltage. Further information can also be derived from the data. FIG. 4 shows a threshold range 42 of values over which the threshold voltage of the different transistors 51 of the array 50 may vary.

The current of signal electrons detected from the via or contact metal of a transistor 51 depends on the extent to which the transistor 51 is switched on, i.e. the extent to which current may flow between the source electrode 52 and the drain electrode 53. When a sufficiently low current (or no current) flows between the source electrode 52 and the drain electrode 53, then charges may accumulate at the drain electrode 53.

For some types of transistor 51, positive charge may accumulate. The accumulated positive charge may reduce the possibility of secondary electrons from reaching the detector. This reduces the number of secondary electrons that reach the detector 144. This may result in a dark spot in any SEM image, for example, that is generated. In contrast, when current may flow freely between the source electrode 52 and the drain electrode 53, then secondary electrons may be more free to reach the detector 144 of the electron beam tool 100. This may result in a higher voltage contrast signal and a lighter spot in any SEM image, for example, that is generated.

At least some embodiments are expected to reduce the area required for test structures for testing a given number of devices. In particular, known test structures require large areas as metal pads may take several micrometres area. Such areas are required for each individual transistor to be tested. At least some embodiments are expected to allow orders of magnitude more transistors 51, for example, to be tested for a given area.

At least some embodiments are expected to increase the number of statistics that can be measured for devices of a given type. Using known techniques only tens to hundreds of transistors of a given type may be measured using electrical testing for the whole of a substrate. This provides a limited number of statistics. At least some embodiments are expected to greatly increase the numbers of transistors of a given type that can be measured, thereby improving the statistics (e.g. characteristics) that can be measured. Such statistics may help manufacturers to determine the possible ranges of structural design features of a device in order for the device to have the desired characteristics/properties. For example, if it is known that a transistor is required to have a given mean threshold voltage and a given standard deviation of that threshold voltage, then it can be determined what dimensions of the electrodes are required in order to meet those requirements.

At least some embodiments are expected to provide improved failure analysis. For known test structures, the measured information does not allow for easy failure analysis. One reason is that the measured information may not be particularly local to each transistor. This is because only a small number of transistors can realistically be tested for a given substrate. At least some embodiments are expected to allow a greater number of transistors (or other devices) throughout a substrate to be tested. This allows measured information to be more local to each transistor, thereby making failure analysis easier.

In some embodiments, the signal applied to the control element of each device is applied by a test probe. For example, a nanoprobe may be used to apply and vary the voltage applied to the common control electrode 59. The voltage applied to the common control electrode 59 is applied to the gate electrode 54 of all of the transistors 51 of the array 50. In some embodiments, a test probe is used in parallel with the voltage contrast measurements. In some embodiments, the electron beam tool 100 is configured to support a nanoprobe in parallel with voltage contrast measurements.

The signal may be applied to the control element of the devices simultaneously with scanning the electron beam 55 over the array 50 and detecting the signal electrons from the transistors 51. However, it is not essential for the electric potential to be applied to the gate electrodes 54 simultaneously with the scanning. In some embodiments, the electric potential for the gate electrodes 54 may be applied initially. The application of the electric potential may then be suppressed (e.g., stopped) during the scan. The already applied electric potential for the gate electrodes 54 may be stable during the scan. Provided that the electric potential is stable during the scan, it may not be necessary to actively apply the voltage to the gate electrodes 54 during the scan.

It is not essential to apply the signal to the control elements of the devices by a test probe. Alternative ways of applying a signal such as the gate voltage are described below.

In some embodiments, the signal applied to the control element of each device is applied by directing (e.g., projecting) a further charged particle beam to a common control contact connected to a plurality of the switches. For example, a second electron beam may be used to supply the gate voltage. In some embodiments, the electron beam tool 100 is configured to project multiple electron beams. One of the multiple electron beams may be used to supply a gate voltage, for example by projecting the electron beam onto the common control contact 59. One or more other electron beams 55 may be projected onto the vias connected to the drain electrodes 53 of the transistors 51 of the array. This may allow the gate voltage to be applied simultaneously with performing the scan of the array 50.

In some embodiments, the common control contact 59 is at least 500 nm, optionally at least 1 μm, optionally at least 2 μm, optionally at least 5 μm and optionally at least 10 μm away from the transistors 51. A greater distance between the common control contact 59 and the transistors 51 may make it easier to distinguish between signal electrons coming from the electron beam on the common control contact 59 and the signal electrons coming from the electron beams 55 projected onto the transistors 51.

In some embodiments, the signal applied to the control element of each device is applied by projecting a charged particle beam onto a common control contact 59 connected to a plurality of the control elements before projecting the charged particle beam onto a second electrode of each device. The common control contact 59 has a capacitance such that the signal applied to the control element of each device is maintained while monitoring the signal charged particles from the second electrode of each device. The electron beam tool 100 may not be required to project multiple electron beams. In some embodiments, the electron beam tool 100 is configured to project a single beam. The common control contact 59 may have a capacitance large enough to be charged by the electron beam and hold a desired voltage steadily during the voltage contrast scan of the transistors 51.

In some embodiments, light may be used to supply the transistors 51 with an effective gate voltage. For example, in some embodiments, the electron beam tool 100 may comprise a light source configured to project photons onto the array 50. Photons may impinge on all transistors 51, for example, and generate electron/hole pairs in the transistor channels. The light may induce a conductive path between the source electrode 52 and the drain electrode 53 of each transistor 51. In some embodiments, the light source is configured to apply the light simultaneously with a scan of the devices by the electron beam 55.

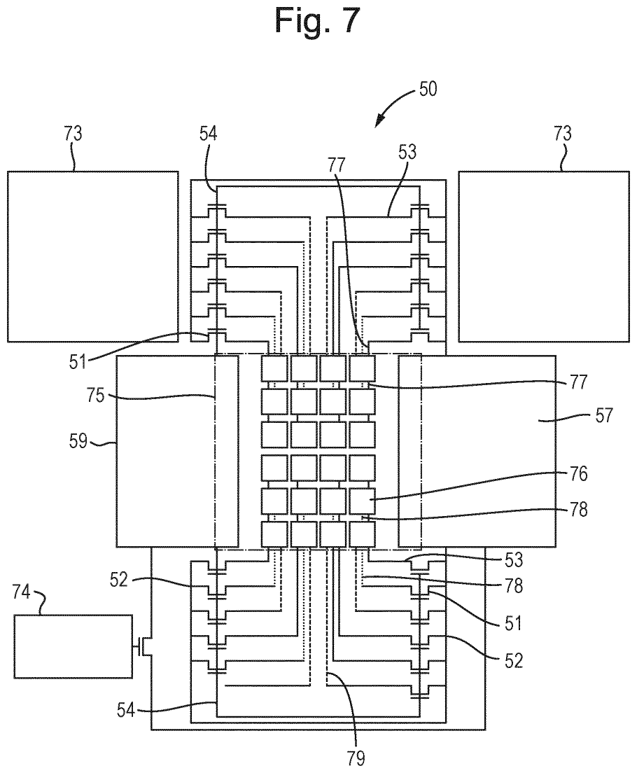

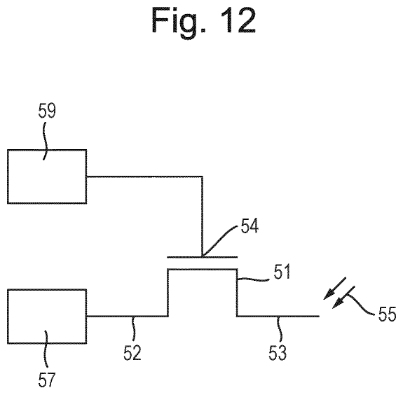

FIG. 12 is a diagram showing a generic implementation of transistor measurement with an electron beam 55. As shown in FIG. 12, a transistor 51 is connected to a control contact 59 and a reference contact 57. The drain electrode 53 (or in an alternative implementation the source electrode 52) is exposed and scanned with the electron beam 55. The arrangement shown in FIG. 12 can be repeated, arranged and connected in various ways, for example as shown in FIG. 3. FIG. 3 shows a two-dimensional array in which the transistors 51 are in an array 50 and share a common control contact 59 and a common reference contact 57. Another possibility is to locate transistors 51 around electronic structures more irregularly as described with reference to FIG. 7, for example. In a further alternative, multiple transistors are electrically coupled to different control contacts instead of a common control contact.

As described above and as shown in FIG. 3, in some embodiments, the devices are transistors 51. However, it is not essential for the devices to be transistors. In some embodiments, the devices are DRAM structures 61.

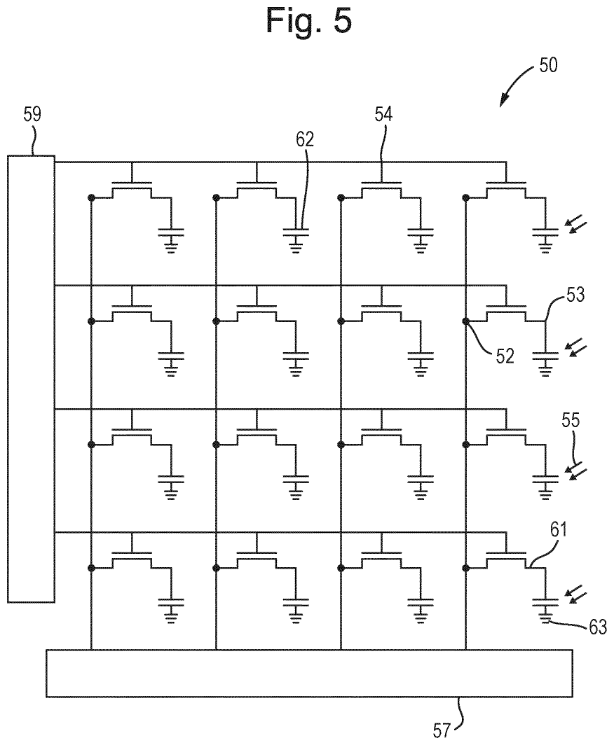

FIG. 5 is a diagram of an array 50 of DRAM structures 61. As shown in FIG. 5, in some embodiments, the DRAM structures 61 are arranged in a two-dimensional grid. The DRAM structures 61 may be arranged in a regular pattern. The DRAM structures 61 may be arranged in a plurality of columns and rows of a grid. The array 50 of DRAM structures 61 may be dual purpose. The array 50 may be used for both testing the devices and as a functional part of a circuit, for example for use as memory.

In some embodiments, each DRAM structure 61 comprises a source electrode 52, a drain electrode 53 and a gate electrode 54. Some of the features of the arrangement shown in FIG. 5 may be the same as shown in FIG. 3. For example, a common control contact 59 may be connected to all of the gate electrodes 54 of the DRAM structures 61. A common reference contact 57 may be electrically connected to the source electrode 52 of all of the DRAM structures 61.

A difference between the array 50 of DRAM structures 61 and the array 50 of logic transistors 51 is that the drain electrodes 53 in the array 50 of DRAM structures 61 are connected to a capacitor 62. In contrast a logic transistor does not have such a capacitor. Each DRAM structure 61 comprises a respective capacitor 62 connected to its drain electrode 53. The capacitor 62 may be electrically located between the drain electrode 53 and a terminal 63 connected to a via exposed at the surface of the substrate. In such a set-up, the read out is done with an electron beam 55 inducing a current that enters the capacitor 62 of each DRAM structure 61 through the exposed via.

When the electron beam 55 is incident on the DRAM structures 61, the capacitors 62 will charge up if the electric potential applied to the gate electrode 54 is such that the transistors are switched off. In contrast, the capacitors 62 do not charge up if the gate voltage is such that the transistors are switched on. Plotting the voltage contrast signal of the capacitors 62 against the gate voltage gives a similar set of curves as shown in FIG. 4. When the gate voltage is below the threshold voltage of the DRAM structure 61, the capacitor 62 is charged and the voltage contrast signal is low. At a larger gate voltage, the charge does not accumulate in the capacitor 62 which leads to a larger voltage contrast signal.

In some embodiments, the device may be another type of device having an electrical connection between two electrodes controllable by a signal applied to a control element. For example, in some embodiments, the devices are photodiodes. The signal applied to the control elements may be a photon signal, for example light.

In some embodiments, the photon signal is varied by varying the intensity of light applied to the light-sensitive control element of the photodiode. The intensity of light may be swept from low intensity to high intensity, for example. There may be a threshold intensity for each photodiode at which current begins to flow between the two electrodes of the photodiode.

Additionally or alternatively, the wavelength of the photon signal may be swept through a range of wavelengths. There may be a threshold wavelength at which the photodiode control elements on or control elements off. By sweeping through a range of wavelengths, the wavelengths that switch on/off each photodiode may be measured. Of course a photon signal, e.g., a light beam, may comprise a range of wavelengths. In some embodiments, the wavelength of the photon signal is the dominant wavelength of the photon signal, for example the wavelength of greatest intensity.

In some embodiments, the method comprises determining for each device at least one of a threshold signal (e.g., a threshold voltage), a leakage current and a sub-threshold slope. These values may be determined from the monitored signal particles. For example, these values may be determined from the curves 41 shown in FIG. 4.

The threshold voltage may be determined as the gate voltage at which the voltage contrast signal increases above a threshold level. It may not be necessary to determine the threshold voltage for each transistor 51 individually. In some embodiments, it may be sufficient to determine the average (e.g., mean) threshold voltage for the array 50 of transistors 51 as a whole. Alternatively, it may not be required to measure the threshold voltage at all.

The leakage current is the current between the source electrode 52 and the drain electrode 53 when the transistor 51 is switched off (e.g., when the electric potential applied to the gate electrode 54 is equal to the reference electric potential applied to the source electrodes 52). The leakage current may also be referred to as the dark current.

In some embodiments, the signal electrons detected by the detector 144 may comprise backscattered electrons and secondary electrons. The current of backscattered electrons detected by the detector 144 may be expected to remain substantially constant regardless of the electric potential applied to the gate electrode 54. In contrast, the current of secondary electrons may be expected to vary depending on the gate voltage. The constant current of backscattered electrons may be known. By measuring the detector current, the current of secondary electrons may be determined.

The sub-threshold slope relates to the shape of the curves 41 shown in FIG. 4 below the threshold voltage. The sub-threshold slope is the slope of the curve 41 before the transistor 51 control elements on.

In order to determine some properties of the transistors 51, it may be necessary to calibrate the detected values. For example, it may be desirable to correlate the signals measured by the electron beam tool 100 to the actual current passing through the substrate. Calibration could be done by having an SEM image of one or more devices of known properties.

Additionally or alternatively to calibrating the system may be modelled mathematically, as set out below. This may allow one or more properties of the transistors 51 to be measured.

The voltage contrast signal may be represented as a gray level value (GLV) by the electron beam tool 100. The current I_{d} detected by the detector 144 relates to the GLV by:

$$G L V = {a}_{1} {e}^{{a}_{2} C} {I}_{d} + {a}_{3} B + {a}_{4}$$

where aᵢ are amplifier gain coefficients, B is brightness and C is contrast.

The detector current consists of the secondary electron (SE) current and the backscattered electron (BSE) current:

$${I}_{d} = {I}_{d - S E} + {I}_{d - B S E} = δ {I}_{p} + η {ε}_{C} {I}_{p}$$

where δ (η) is the SE (BSE) electron yield and ε_{C} is the collection efficiency of the detector 144 for BSEs. Iₚ is the primary beam electron current. The BSE yield is not affected by the charging occurring when irradiating the via, so we can assume we know its value. That is not the case for the SE yield. Measuring the detector current and assuming one knows the BSE current component, one finds the SE current component.

The charging occurring at the via follows the charge conservation:

$${I}_{P} + {I}_{d e v i c e} = δ {I}_{p} + η {I}_{p}$$

The two parts of the right-hand side and the primary beam current may be known or determined. The device current can be calculated. Upon scanning an electron beam on the exposed via of transistors, charges are created and then neutralized to some degree depending on how well the via is connected to a source of free charges. Assuming that all the contact charge neutralization would flow from a transistor channel, the device current identifies to the drain-source current of a transistor.

Adding a model for the secondary electron yield emission of the metal contact, it is possible to convert the measured SE current into the drain-source voltage of the transistor. This model in the case of positive charging can be found in the literature and reads:

$$δ = {δ}_{0} \frac{{φ}^{2} ( φ + 3 e {V}_{s} )}{{( φ + e {V}_{s} )}^{3}}$$

where δ₀ is the SE yield of the via in absence of charging, φ is its work function and Vₛ is the voltage that develops between the surface of the via and the drain, when we neglect the current flowing through the substrate underneath the contact. Assuming δ₀ is known, the measured SE current gives the drain source voltage.

In some embodiments, the method comprises varying a current of the charged particle beam applied to the second electrode of each device while maintaining the signal applied to the control element of each device. In some embodiments, the method comprises monitoring signal charged particles from the second electrode of each device for the varying current. For example, the primary beam current (i.e., the current of the electron beam 55) may be changed. This may make it possible to plot a source-drain current versus a source-drain voltage at a given gate voltage. In some embodiments, the method comprises determining for each device a relationship between a potential difference between the two electrodes and a current between the two electrodes.

In some embodiments, the secondary electron yield model may be calibrated. In order to know the secondary electron yield of the via exposed at the surface of the substrate, it may be desirable to measure the current of secondary electrons in the absence of charging. In order to avoid charging, it may be desirable to make sure that enough charges can flow between the drain electrode 53 and the source electrode 52, for example, of the transistor 51. The charges may then flow to the contact for neutralisation, thereby avoiding charging at the exposed via.

In some embodiments, the method comprises applying a saturation signal to the control element of each device. For example, the electric potential applied to the gate electrodes 54 may be set to be large (above the expected threshold voltages of the transistors 51). This may result in the maximum current as secondary electrons from the via exposed at the surface of the substrate. Additionally or alternatively, the method may comprise projecting light onto each device such that the two electrodes are electrically connected in substantially all of the devices. For example, a light beam may be illuminated on the array 50 so as to control the accumulated charges due to effects such as photoconductivity, photoelectric or thermal effects. This may lead to saturation of the signal electrons from the exposed via. This may allow the second electron yield of the metal of the exposed via to be known.

In some embodiments, the method comprises monitoring signal charged particles from the second electrode of each device while suppressing (e.g., stopping) projection of the charged particle beam onto the second electrode of each device. The secondary electron current may be measured in the absence of charging.

In some embodiments, the charged particle-optical apparatus is for testing the array 50 of devices. The apparatus comprises a reference voltage supply. The reference voltage supply is configured to supply a reference electric potential to the first electrode of each electrodes of each device. For example, the reference voltage supply may be electrically connected to the common reference contact 57. The reference voltage supply may be simply the reference ground potential for the apparatus (e.g., electron beam tool 100).

In some embodiments, the apparatus comprises a charged particle-optical device configured to project a charged particle beam onto a second electrode of the two electrodes of each device. For example, an electron beam tool 100 as shown in FIG. 2A, FIG. 2B or FIG. 2C may be employed to project an electron beam onto the drain electrodes 53 of the transistors 51.

In some embodiments, the apparatus comprises a signal supply. The signal supply is configured to vary a signal applied to the control element of each device. For example, the signal supply may comprise a voltage supply electrically connected to the common control contact 59. The signal supply may comprise a test probe configured to electrically connect to the common control contact 59 so as to apply the varying signal (e.g., electric potential).

Alternatively, the signal supply may comprise a controllable light source for emitting light of a controlled intensity and/or wavelength.

In some embodiments, the apparatus comprises a detector 144 for monitoring, for each signal applied, signal charged particles from the second electrode of each device. The detector may be as described above in the context of FIG. 2A, FIG. 2B or FIG. 2C, for example.

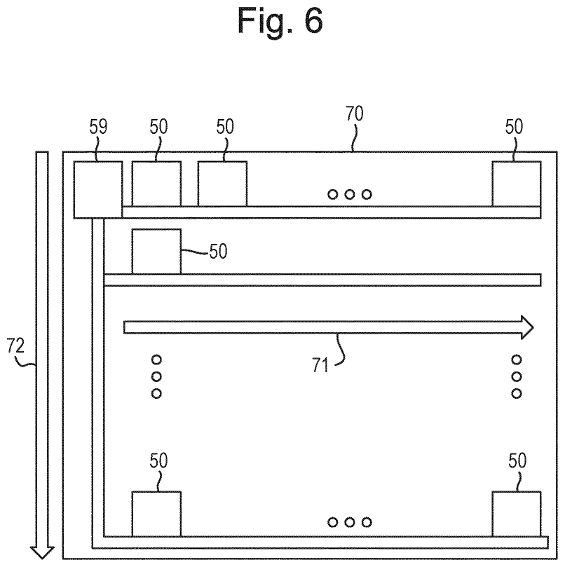

FIG. 6 is a schematic diagram of a mark 70. As shown in FIG. 6, in some embodiments, the mark 70 comprises a plurality of DUTs. the DUTs may be arranged in a two-dimensional grid. The grid may comprise columns and rows. In FIG. 6 not all of the DUTs are shown. As suggested in FIG. 6, the mark 70 may comprise a plurality of columns and rows of DUTs arranged in a regular pattern. Each DUT may comprise an array 50 of devices. For example, there may be of the order of 1000 devices in each array 50 of the mark 70. The mark 70 may be provided in a substrate.

As shown in FIG. 6, in some embodiments, a common control contact 59 is electrically connected to the control element of each device of the arrays 50. For example, the common control contact 59 may be connected to the gate electrode 54 of all of the transistors 51 of all of the arrays 50 of the mark 70. The mark 70 may contain arrays 50 of transistors 51.

In some embodiments, at least one structural feature of the devices varies in a predetermined way across the array or mark 70. For example, within each array 50 of the mark 70, all of the transistors 51 may be designed to be of the same type. However, between the arrays 50, there may be one or more structural differences intended. For example, in some embodiments, the at least one structural feature that varies in the predetermined way comprises at least one of an overlay shift between layers of the device and a dimension of a component of the device.

In some embodiments, the mark 70 comprises a column variation 71. For example, the column variation 71 may be a program overlay shift between two layers of the devices. In some embodiments, the mark 70 comprises a row variation 72. For example, the row variation may be increasing dimension of the gate electrode 54 of the devices.

By sweeping through the gate voltages as described above, for example, it is possible to measure how the threshold voltage and/or other parameters of the devices depend on the programmed variations of the devices. This may help designers to identify possible values of different dimensions and acceptable values for overlay that will lead to acceptable results.

For example, in some embodiments, in each DUT (e.g., each array 50) it is possible to count the number of transistors 51 that are switched on and off for each applied gate voltage. For each DUT, it is possible to determine a yield number, which may be the ratio of transistors that are switched on to overall number of transistors. The relationship between the yield number and the overlay or dimension (e.g., critical dimension) can be investigated. Additionally or alternatively, the relationship between one or more parameters such as threshold voltage and geometrical variations in the design of the devices may be investigated.

FIG. 7 schematically shows an arrangement of devices that is alternative to the arrangement shown in FIG. 3, for example. In some embodiments, devices are arranged in an array 50. In the example shown in FIG. 7, the devices are transistors 51. As shown in FIG. 7, the transistors 51 may be arranged in lines. However, the transistors 51 may be arranged differently and are not required to be provided in any regular pattern. The transistors 51 may be arranged irregularly.

The transistors 51 may be located to have a particular context. The context means the environment of the transistors 51. For example, the context of the transistors 51 may relate to where on a substrate the transistors 51 are positioned (e.g., how far from the edge of the substrate), and/or what types of structures are located adjacent to the transistors 51. Different types of structures may have different respective manufacturing processes associated with them. Depending on the manufacturing processes of structures in the vicinity of the transistors 51, the manufacturing processes may affect the properties of the transistors 51. At least some of the embodiments are expected to enable assessment of how the context of transistor 51 (or other types of device) may affect its properties.

As shown in FIG. 7, in some embodiments, the substrate that comprises the transistors 51 comprises electrode contact 76. In some embodiments, the electrodes onto which the electron beam is directed are connected to respective electrode contacts 76. The electrode contacts 76 are exposed at the surface of the substrate. The electrode contacts 76 may be pads, for example metal pads. In the arrangement shown in FIG. 7, the drain electrodes 53 are connected to respective electrode contacts 76. Alternatively, the source electrodes 52 may be connected to the respective electrode contact 76 and the drain electrodes 53 may be connected to the reference potential.

As shown in FIG. 7, the electrode contacts 76 may be distanced from the drain electrodes 53. As shown in FIG. 7, in some embodiments, the electrode contacts 76 are arranged in a contact area. The contact area may be distanced from the drain electrodes 53, the source electrode 52 and/or the gate electrodes 54. By distancing the electrode contacts 76 from the transistors 51, the transistors 51 are less likely to be undesirably affected by the electron beam being used to charge the electrode contacts 76. The drain electrodes 53 may be charged indirectly by the electron beam. The electron beam may be directly incident on the electrode contact 76. The electrode contacts 76 are electrically connected to their respective drain electrodes 53. The electron beam is indirectly directed to the drain electrodes 53 via the electrode contacts 76.

By physically locating the electrode contacts 76 away from the transistors 51, the possibility of undesirably inducing capacitive effect on the transistors by the application of the electron beam is reduced. For example, the likelihood of the electron beam undesirably charging the gate electrodes 54 may be reduced. At least some embodiments are expected to improve the accuracy of assessing transistors 51. During the assessment for the transistors 51, any undesirable disturbance to the transistors 51 as a result of the electron beam may undesirably affect the accuracy of the assessment.

As shown in FIG. 7, the contact area may comprise the electrode contact 76 in a compact way. For example, the electrode contacts 76 may be arranged in an array such as a two-dimensional array. The electrode contacts 76 may be arranged in a plurality of rows and/or columns. The electrode contacts 76 may be arranged in a regular arrangement. At least some embodiments are expected to reduce the overall area over which the electron beam is required to be scanned in order to assess the transistors 51. By arranging the electrode contacts 76 compactly, the required scan range may be reduced. This may reduce the time required for the assessment.

As shown in FIG. 7 the substrate may comprise one or more electronic structures 73. The electronic structures 73 may be located close to, for example adjacent to, the transistors 51. The electronic structures 73 may form part of the context of the transistors 51 that are to be tested. The electronic structures 73 may be electronic products or part of electronic products. The electronic structures may comprise transistors and/or memory devices such as DRAM and/or SRAM. The electronic structures 73 may comprise processors for performing processes.

By locating the transistors 51 in the vicinity of the electronic structures 73, the transistors 51 may better represent the properties of the devices of the electronic structures 73. By locating a transistor 51 near a particular electronic structure 73, it is possible to assess effects (which may be referred to as proximity effects) that the electronic structure 73 may have on the properties of the transistor 51. At least some embodiments are expected to improve the accuracy of assessing devices of electronic structures that may be electronic products or part(s) of electronic products.

As shown in FIG. 7, in some embodiments, the gate electrodes 54 are connected to a common control contact 59. However, it is not essential for a common control contact 59 to be provided. In some embodiments, the gate electrodes 54 may be connected to respective individual control contacts. In a further alternative, the gate electrode 54 may be grouped together in groups, each group comprising a plurality of gate electrodes 54. All of the gate electrodes 54 of a group may be connected to a common group control contact. A plurality of group control contacts may be provided for a respective plurality of groups of data electrodes 54.

As shown in FIG. 7, in some embodiments, the common control contact 59 is adjacent to the contact area in which the electrode contacts 76 are provided. As shown in FIG. 7, in some embodiments, the substrate comprises a scan area 75. The scan area 75 may correspond to an area of the surface of the substrate that is to be scanned by the electron beam. As shown in FIG. 7, the contact area of the electrode contacts 76 may be within the scan area 75. The electrode contacts 76 are scanned during scanning of the electron beam across the substrate. As shown in FIG. 7, the scan area 75 may be much smaller than the overall size of the substrate. At least some embodiments are expected to reduce the scan area required in order to access the transistors 51. For example, as shown in FIG. 7, the electrode contacts 76 may be arranged in a relatively small contact area.

As shown in FIG. 7, in some embodiments, at least part of the common control contact 59 is within the scan area 75. During scanning of the electron beam across the surface of the substrate, the common control contact 59 may be scanned by the electron beam. In some embodiments, the electron beam is directed on to the common control contact 59 in the same scan lines as are used to scan the electrode contact 76. As shown in FIG. 7, in some embodiments, at least part of the common reference contact 57 is within the scanned area 75. In some embodiments, the electron beam is directed on to the common reference contact 57. For example, in some embodiments, the electron beam may be scanned using a frame scan mode. A frame scan comprises scanning the electron beam along a plurality of substantially parallel lines. For example, the electron beam may be scanned along a first line horizontally from a top left corner of the scan area 75 to the top right corner of the scanned area shown in FIG. 7. A subsequent scan line may be parallel to the scan line and slightly below. By scanning the lines in turn, the whole of the scanned area 75 may be scanned by the electron beam.

As shown in FIG. 7, in some embodiments, each line of the frame scan comprise scanning part of the common control contact 59 and/or part of the common reference contact 57 in addition to a plurality (e.g., a row) of the electrode contact 76. As shown in FIG. 7, in some embodiments, the scan area 75 comprises the electrode contacts 76, at least part of the common control contact 59 and at least part of the common reference contact 57. It is possible to show the omitted electrons from each region within a single image.

In some embodiments, within each line of the scan, the electron beam is directed on to the common control contact 59 before the row of electrode contacts are scanned. In some embodiments, the electron beam is directed on to the common reference contact 57 after the electron beam has been directed on to the plurality (e.g., row) of electrode contact 76.

As shown in FIG. 7, in some embodiments, the substrate comprises a plurality of electrical traces 77 to 79. The electrical traces electrically connect the electrode contact 76 to the respective drain electrodes 53. If there is sufficient space, then the electrical traces 77 to 79 may be arranged adjacent to each other. The electrical traces may be provided at substantially the same level within the substrate.

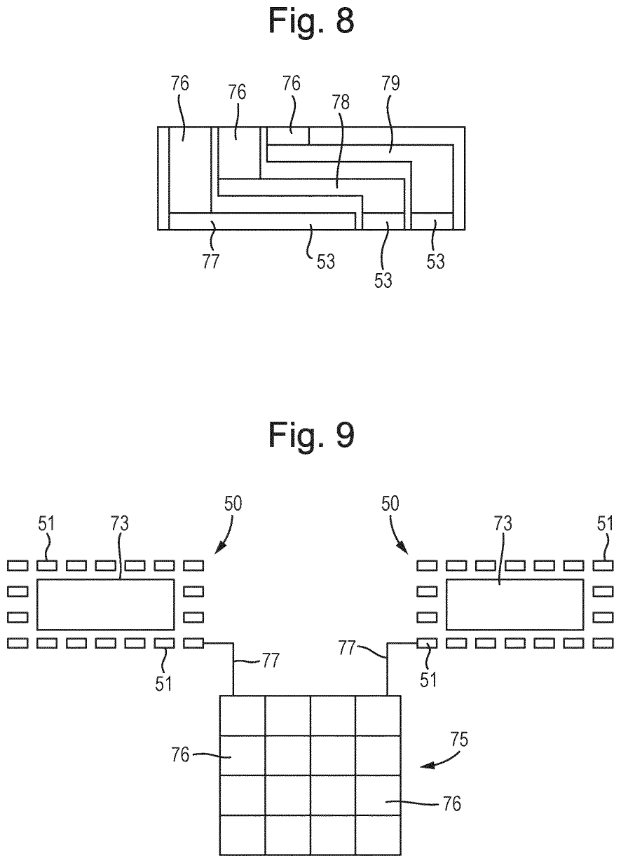

Alternatively, the electrical traces 77 to 79 may be provided at different levels within the substrate. The electrical traces 77 to 79 may be arranged to extend across the substrate at different levels within a substrate. This is shown in FIG. 8. As shown in FIG. 8, there may be a plurality (e.g., three) levels within their substrate that which the electrical traces 77 to 79 extend. Each electrical trace 77 to 79 electrically connects a drain electrode 53 to a respective electrode contact.

As shown in FIG. 8, in some embodiments, a first electrical trace 77 is provided at a lowest level amongst the electrical traces 77 to 79. A second electrical trace 78 is provided at an intermediate level within the substrate. A third electrical trace 79 is provided at a highest level within the substrate. By providing electrical traces 77 to 79 at different levels, the electrical traces 77 to 79 may take up less space across the substrate.

As shown in FIG. 7, in some embodiments, the substrate comprises a reset switch 74. The reset switch 74 may comprise a transistor, for example. In some embodiments, charging of the gate electrode of the transistor of the reset switch 74 is controlled so as to control whether or not the gate electrode 54 of the transistors 51 are connected to the reference potential. In the arrangement shown in FIG. 7, the reset switch 74 is configured to control whether the common reference contact 59 is in an electrical contact with the common control contact 59. When the electrical connection is provided, then the gate electrodes 54 are discharged. This allows the assessment of the transistors 51 to be performed again (for example a repeat test) without the subsequent test undesirably being affected by the previous test.

In some embodiments, reset switch 74 is closed by directing an electron beam onto the reset switch 74, for example onto the gate electrode or a pad which is connected to the gate electrode. The reset switch 74 may then be reopened by allowing the charge to leak away (e.g., through gate leakage). Alternatively, the properties of the electron beam may be changed, and the electron beam may again be directed on to the reset switch 74 so as to negatively charge the gate electrode of the reset switch 74. For example, the landing energy of the electrons of the electron beam may be adjusted so as to oppositely charge the gates electrode of the reset switch 74.

Alternatively, the reset switch 74 may be closed by illuminating the reset switch 74 with light (e.g., using photo-induced conductivity). This may close the reset switch 74 temporarily while the light is incident on the reset switch 74. The light may be turned off so as to reopen the reset switch 74. By using light, the reset switch 74 may be expected to reopen more quickly compared to if an electron beam is used to control the reset switch 74.

FIG. 9 is a schematic view of an alternative arrangement of devices such as transistors 51. As shown in FIG. 9, in some embodiments, the transistors 51 are arranged in a plurality of arrays 50. However, it is not essential for the transistors 51 to be arranged in arrays 50. The transistors 51 can be reorganized as desired and are not required to be organised in one line.

For example, as shown in FIG. 9, in some embodiments, the transistors 51 are arranged around one or more electronic structures 73. In the example shown in FIG. 9, one set of transistors 51 are arranged surrounding one electronic structure 73 and another group of transistors 51 surround another electronic structure 73. The transistors 51 may be located adjacent to the electronic structures 73. The transistors 51 may have properties that are more accurately representative of the properties of transistors or other devices that form part of the electronic structures 73.

As shown in FIG. 9, in some embodiments, the scan area 75 is distanced from the transistors 51. The electrode contacts 76 may be provided within the scan area 75.

The transistors 51 may be located in various different positions in the substrate. For example, different transistors 51 may be located in different contexts, for example close to different types of electronic structures 73 or different types of devices having different manufacturing processes. As shown in FIG. 9, electrical traces 77 may be provided for electrically connecting the electrode contacts 76 to the transistors 51. In some embodiments, the electron beam is scanned over only one field of view, i.e., the scan area 75, while having access to the effect of different contexts on electrical metrics of the transistors 51. In FIG. 9, the electrical traces 77 between the electrode contacts and the transistors 51 are shown only schematically. In some embodiments, each transistor 51 is electrically connected by an electrical trace 77 to a respective electrode contact 76.

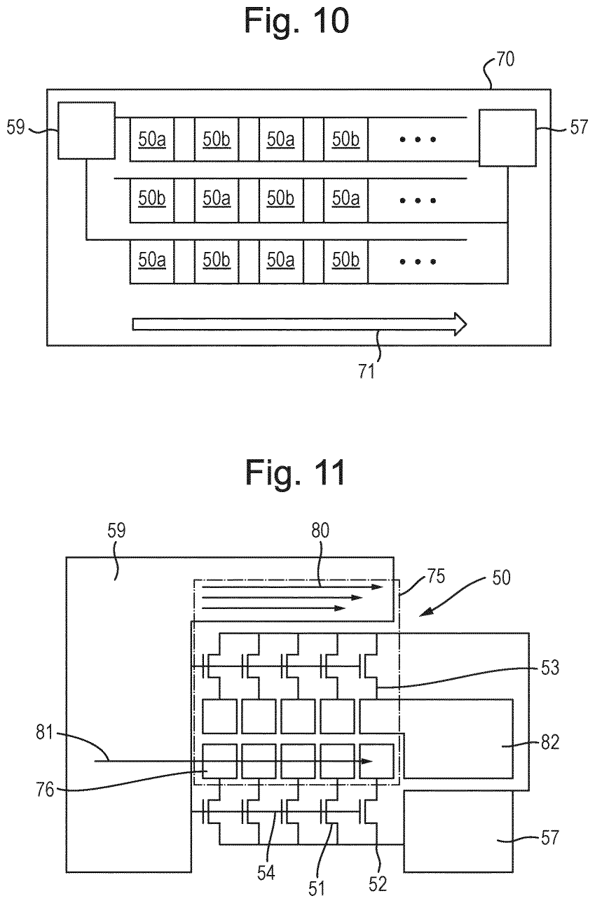

FIG. 10 is a diagram showing a mark 70 comprising arrays 50 of devices such as transistors. Features that are the same as the arrangement shown in FIG. 6 are not described again in detail below. For example, the common control contact 59 and the common reference contact 57 may be as described elsewhere.

As shown in FIG. 10, in some embodiments, the mark 70 comprises a column variation 71. For example, the column variation 71 may be a programmed overlay shift between two layers of the devices. Alternatively, the column variation could be, for example, increasing dimension of the gate electrode 54 of the devices.

As shown in FIG. 10, in some embodiments, the mark 70 comprises an arrangement of arrays 50. In some embodiments, the arrays 50 are of different types of devices. For example, some of the arrays 50A are arrays of transistors that have a relatively high threshold voltage. Another plurality of the arrays 50B may be of transistors that have a relatively low threshold voltage.

As shown in FIG. 10, in some embodiments, the mark 70 comprises a mixture of devices of different types, such as a mixture of high and low threshold voltage transistors. As shown in FIG. 10, in some embodiments, the mark 70 comprises an array of arrays 50.

The mark 70 may be used to incorporate geometrical variations and proximity effects by mixing arrays 50 of different types of transistors. Although not shown in FIG. 10, there may be a row variation in addition to the shown column variation 71. The different types of transistors may be formed using different manufacturing processes. The manufacturing processes used to manufacture the high threshold voltage transistors may have an unintended effect on the properties of the low threshold voltage transistors. Similarly, the manufacturing processes for the low threshold voltage transistors may have an unintended effect on the properties of the high threshold voltage transistors. By arranging different types of transistors close to each other, the effects of the manufacturing processes of devices close by may be measured.

By providing the column variation and/or the row variation, the best process window may be found. For example, it may be determined for which overlays the properties (metrics) of the transistors 51 are within specification, i.e., acceptable, and for which overlays the metrics are out of specification. This helps to define the overlay window, i.e., where the manufacturing process has acceptable results.

As shown in FIG. 10, in some embodiments, a common reference contact 57 may be provided for a plurality, or all of the arrays 50. As shown in FIG. 10, in some embodiments, a common control contact 59 may be provided for a plurality of, or optionally all of, the arrays 50 of the mark 70.

FIG. 11 is a diagram showing an alternative arrangement of transistors 51 to be tested. As shown in FIG. 11, in some embodiments, the transistors 51 are arranged in an array 50. However, the transistors 51 may be arranged more irregularly.

Features shown in FIG. 11 that are also shown in other figures are not described again below for brevity. For example, the common reference contact 57, the common control contact 59, the transistors 51 and the electrode contacts 76 may be as described elsewhere. As shown in FIG. 11, in some embodiments, the substrate comprises a probe contact 82. The probe contact 82 may be referred to as a probe measurement site. The probe contact 82 is exposed at the surface of the substrate. In some embodiments, the probe contact 82 comprises a pad, for example a metal pad.

As shown in FIG. 11, in some embodiments, the probe contact 82 is electrically connected to one of the electrode contacts 76. For example, in some embodiments, the probe contact 82 and the connected electrode contact 76 may be formed integrally with each other. For example, a single metal pad may be provided to function as both the probe contact 82 and the connected electrode contact 76. Alternatively, the probe contact 82 and the connected electrode contact 76 may be provided as separate contacts which are electrically connected, for example by an electrical trace.

As shown in FIG. 11, in some embodiments, the probe contact 82 is larger than the electrode contacts 76. The probe contact 82 may be large enough for a physical probe to rig electrical contact with the probe contact 82. The electrode contacts 76 may not be required to be large enough to be accessible with a physical probe.

In some embodiments, the probe contact 82 is for electrically connecting the connected electrode contact 76 to a probe. By providing the probe contact 82 as a larger pad, physical tips of probes may be used to connect to the probe contact 82.

In some embodiments, a calibration method comprises connecting probes to a plurality of the probe contact 82, the common reference contact 57 and the common control contact 59. The probes may be used to measure current and/or voltage.

As shown in FIG. 11, in some embodiments, the scan area 75 comprises the electrode contacts 76. The scan area 75 may comprise part of the common control contact 59.

As shown in FIG. 11, in some embodiments, the scan area 75 is scanned by the electron beam by scanning a plurality of substantially parallel lines 80. The lines 80 may be scanned sequentially so as to scan the whole of the scan area 75.

In some embodiments, the common control contact 59 is scanned before the electrode contacts 76 are scanned. The common control contact 59 may be charged before the electrode contacts 76 are scanned by the electron beam. In some embodiments, the scan area 75 is scanned using a frame scan mode.

FIG. 11 shows an alternative scan mode. In particular, in some embodiments, the electrode contacts 76 are scanned in a line scan mode. In the line scan mode, the scan area 75 is not required to be scanned. Instead, a single scan line 81 may be scanned. The scan line may be straight, i.e., linear. In the arrangement shown in FIG. 11, one scan line 81 is shown for scanning half of the electrode contacts 76. In some embodiments, a second scan line would be scanned so as to scan the other half of the electrode contact 76. In some embodiments, the common control contact 59 is discharged between scanning of different scan lines 81.

As shown in FIG. 11, in some embodiments, the scan line 81 covers part of the common control electrode 59 as well as a plurality of the electrode contacts 76. In some embodiments, the common control contact 59 is scanned within the scan line 81 before the electrode contacts 76 are scanned.

In the arrangements described in reference to the figures, the devices such as the transistors 51 are generally provided with respective electrode contacts 76. However, this is not essential. For example, in some embodiments, a plurality of, or all of, the drain electrodes 53 of the transistors 51 are connected to a common electrode contact (not shown), for example by electrically connecting the electrode contact 76 shown in the figures or by providing a large electrode contact 76 connected to the plurality of drain electrodes 53 of the transistors 51. In some embodiments, individual control contacts are provided for the respective transistors 51, for example connected to respective gate electrodes 54. By providing individual control contacts, the transistors 51 may be individually addressable even though they may share a common electrode contact for the drain electrodes 53.

In some embodiments, a non-transitory computer readable medium stores instructions for a processor of a controller (e.g. the controller 109) to carry out a method as described above.

Exemplary embodiments of the present disclosure are set out in the following numbered clauses:

1. A method for testing an array of devices each having an electrical connection between two electrodes controllable by a signal applied to a control element, the method comprising:
applying a reference electric potential to a first electrode of the two electrodes of each device;
directing a charged particle beam onto a second electrode of the two electrodes of each device;
varying a signal applied to the control element of each device; and
monitoring, for each signal applied, signal charged particles from the second electrode of each device.
   2. The method of clause 1, wherein the signal is an electric potential.
   3. The method of clause 2, wherein the control element of a plurality of the devices are connected to a common control contact so as to apply the varying electric potential.
   4. The method of any preceding clause, wherein the signal applied to the control element of each device is applied by a test probe.
   5. The method of any of clauses 1-3, wherein the signal applied to the control element of each device is applied by directing a further charged particle beam to a common control contact connected to a plurality of the control elements.
   6. The method of any of clauses 1-3, wherein the signal applied to the control element of each device is applied by directing a charged particle beam onto a common control contact connected to a plurality of the control elements before directing the charged particle beam onto the second electrode of each device, whereby the common control contact has a capacitance such that the signal applied to the control element of each device is maintained while monitoring the signal charged particles from the second electrode of each device.
   7. The method of clause 6, further comprising directing the charged particle beam onto a common reference contact connected to a plurality of the first electrodes.
   8. The method of clause 7, wherein the charged particle beam is directed onto the common reference contact after directing the charged particle beam onto the second electrode of a plurality of the devices.
   9. The method of clause 1, wherein the signal is a photon signal and the step of varying the photon signal comprises varying at least one of an intensity and a wavelength of the photon signal.
   10. The method of any preceding clause, wherein the first electrode of a plurality of the devices are connected to a common reference potential so as to apply the reference electric potential.
   11. The method of any preceding clause, comprising determining for each device at least one of a threshold signal, a leakage current and a sub-threshold slope from the monitored signal particles for the varying signal.
   12. The method of any preceding clause, further comprising:
varying a current of the charged particle beam applied to the second electrode of each device while maintaining the signal applied to the control element of each device; and
monitoring signal charged particles from the second electrode of each device for the varying current.
   13. The method of clause 12, further comprising determining for each device a relationship between a potential difference between the two electrodes and a current between the two electrodes from the monitored signal particles for the varying signal.
   14. The method of any preceding clause, further comprising:
applying a saturation signal to the control element of each device and/or directing light onto each device, such that the two electrodes are electrically connected in substantially all of the devices; and
monitoring signal charged particles from the second electrode of each device while suppressing direction of the charged particle beam onto the second electrode of each device.
   15. The method of any preceding clause, wherein the second electrodes are electrically coupled to respective electrode contacts arranged in a contact area distanced from the first electrodes and the control elements.
   16. The method of clause 15, wherein the charged particle beam is directed onto the second electrodes by scanning the charged particle beam across the contact area such that the charged particle beam is directed onto the second electrodes indirectly via directing the charged particle beam directly onto the electrode contacts.
   17. The method of clause 16, wherein the scanning comprises scanning the charged particle beam along a plurality of substantially parallel lines.
   18. The method of clause 17, further comprising scanning the charged particle beam along a plurality of substantially parallel lines across a common control contact connected to a plurality of the control elements.
   19. The method of clause 17, wherein scanning each line comprises scanning the charged particle beam across a common control contact electrically coupled to a plurality of the control elements and across a plurality of the electrode contacts.
   20. The method of clause 16, wherein the scanning comprises scanning the charged particle beam along at least one straight line across a common control contact connected to a plurality of the control elements and across the electrode contacts.
   21. The method of any of clauses 18-20, wherein the common control contact is scanned before the electrode contacts are scanned.
   22. A charged particle-optical apparatus for testing an array of devices each having an electrical connection between two electrodes controllable by a signal applied to a control element, the electron-optical apparatus comprising:
a reference voltage supply configured to supply a reference electric potential to a first electrode of the two electrodes of each device;
a charged particle-optical device configured to direct a charged particle beam onto a second electrode of the two electrodes of each device;
a signal supply configured to vary a signal applied to the control element of each device; and
a detector for monitoring, for each signal applied, signal charged particles from the second electrode of each device.
   23. The charged particle-optical apparatus of clause 22, further comprising a substrate at the sample location, the substrate comprising an array of devices each having an electrical connection between two electrodes controllable by a signal applied to a control element.
   24. The charged particle-optical apparatus of clause 23, wherein the devices are logic transistors or DRAM structures.
   25. The charged particle-optical apparatus of clause 23 or 24, wherein at least one structural feature of the devices varies in a predetermined way across the array.
   26. The charged particle-optical apparatus of any of clauses 23-25, wherein the at least one feature comprises at least one of an overlay shift between layers of the device and a dimension of a component of the device.
   27. A substrate comprising in a test region an arrangement of devices each having an electrical connection between a source electrode and a drain electrode controllable by an electric potential applied to a gate electrode, wherein the source electrodes or the drain electrodes are connected to a common reference contact and whichever of the source electrodes and the drain electrodes are not connected to the common reference contact are electrically coupled to respective electrode contacts exposed at a surface of the substrate.
   28. The substrate of clause 27, wherein the arrangement comprises a two-dimensional array.
   29. The substrate of clause 27 or 28, wherein the devices comprise logic transistors or memory structures.
   30. The substrate of any of clauses 27-29, wherein the gate electrodes are electrically coupled to a common control contact.
   31. The substrate of any of clauses 27-30, wherein the electrode contacts comprise separate vias.
   32. The substrate of any of clauses 27-31, wherein the electrode contacts are arranged in a contact area distanced from the gate electrodes and whichever of the source electrodes and the drain electrodes are connected to the common reference contact.
   33. The substrate of clause 32, wherein the contact area is adjacent to a common control contact to which the gate electrodes are electrically coupled.
   34. The substrate of any of clauses 27-33, wherein the electrode contacts are arranged in a two-dimensional array.
   35. The substrate of any of clauses 27-34, wherein the electrode contacts are arranged adjacent to an electronic structure.
   36. The substrate of any of clauses 27-35, wherein the electrode contacts are arranged around an electronic structure.
   37. The substrate of any of clauses 27-36, wherein electrical traces extend between the electrode contacts and whichever of the source electrodes and the drain electrodes that are not connected to the common reference contact.
   38. The substrate of clause 37, wherein the electrical traces extend across the substrate at a plurality of levels within the substrate.
   39. The substrate of any of clauses 27-38, comprising another arrangement of devices having a different target property from the arrangement of devices.
   40. The substrate of claim 39, wherein the arrangements are located adjacent to each other.
   41. The substrate of any of clauses 27-40, comprising a probe contact connected to one of the electrode contacts for electrically connecting the electrode contact to a probe.
   42. The substrate of any of clauses 27-41, further comprising a reset switch configured to selectably couple the gate electrodes to the common reference contact.
   43. The substrate of any of clauses 27-42, wherein the devices are arranged at a pitch of at most about 200 nm, optionally at most about 100 nm and optionally at most about 50 nm.
   44. The substrate of any of clauses 27-43, wherein the arrangement is in a scribe lane of the substrate.
   45. A non-transitory computer readable medium that stores instructions for a processor of a controller to carry out a method for testing an array of devices each having an electrical connection between two electrodes controllable by a signal applied to a control element, the method comprising:
controlling application of a reference electric potential to a first electrode of the two electrodes of each device;
controlling direction of a charged particle beam onto a second electrode of the two electrodes of each device;
controlling variation of a signal applied to the control element of each device; and
controlling monitoring, for each signal applied, of signal charged particles from the second electrode of each device.

A non-transitory computer readable medium may be provided that stores instructions for a processor of a controller (e.g., the controller 109 of FIG. 1) to carry out image inspection, image acquisition, activating charged-particle source, adjusting electrical excitation of stigmators, adjusting landing energy of electrons, adjusting objective lens excitation, adjusting secondary electron detector position and orientation, stage motion control, beam separator excitation, applying scan deflection voltages to beam deflectors, receiving and processing data associated with signal information from electron detectors, configuring an electrostatic element, detecting signal electrons, adjusting the control electrode potential, adjusting the voltages applied to the electron source, extractor electrode, and the sample, etc. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments will be apparent to those skilled in the art from consideration of the specification and practice of the technology disclosed herein. It is intended that the specification and examples be considered as exemplary only, with a true scope and spirit of the invention being indicated by the following claims and above clauses.

The descriptions above are intended to be illustrative, not limiting. Thus, it will be apparent to one skilled in the art that modifications may be made as described without departing from the scope of the claims set out below.

1. A method for testing an array of devices each having an electrical connection between two electrodes controllable by a signal applied to a control element, the method comprising:
applying a reference electric potential to a first electrode of the two electrodes of each device;
directing a charged particle beam onto a second electrode of the two electrodes of each device;
varying a signal applied to the control element of each device; and
monitoring, for each signal applied, signal charged particles from the second electrode of each device.

2. The method of claim 1, wherein the signal is an electric potential.

3. The method of claim 2, wherein the control element of a plurality of the devices are connected to a common control contact so as to apply the varying electric potential.

4. The method of claim 1, wherein the signal applied to the control element of each device is applied by a test probe.

5. The method of claim 1, wherein the signal applied to the control element of each device is applied by directing a further charged particle beam to a common control contact connected to a plurality of the control elements.

6. The method of claim 1, wherein the signal applied to the control element of each device is applied by directing a charged particle beam onto a common control contact connected to a plurality of the control elements before directing the charged particle beam onto the second electrode of each device, whereby the common control contact has a capacitance such that the signal applied to the control element of each device is maintained while monitoring the signal charged particles from the second electrode of each device.

7. The method of claim 6, further comprising directing the charged particle beam onto a common reference contact connected to a plurality of the first electrodes.

8. The method of claim 7, wherein the charged particle beam is directed onto the common reference contact after directing the charged particle beam onto the second electrode of a plurality of the devices.

9. The method of claim 1, wherein the signal is a photon signal and the step of varying the photon signal comprises varying at least one of an intensity and a wavelength of the photon signal.

10. The method of claim 1, wherein the first electrode of a plurality of the devices are connected to a common reference potential so as to apply the reference electric potential.

11. The method of claim 1, comprising determining for each device at least one of a threshold signal, a leakage current and a sub-threshold slope from the monitored signal particles for the varying signal.

12. The method of claim 1 comprising:
varying a current of the charged particle beam applied to the second electrode of each device while maintaining the signal applied to the control element of each device; and
monitoring signal charged particles from the second electrode of each device for the varying current.

13. The method of claim 12, comprising determining for each device a relationship between a potential difference between the two electrodes and a current between the two electrodes from the monitored signal particles for the varying signal.

14. The method of claim 1 comprising:
applying a saturation signal to the control element of each device and/or directing light onto each device, such that the two electrodes are electrically connected in substantially all of the devices; and
monitoring signal charged particles from the second electrode of each device while suppressing direction of the charged particle beam onto the second electrode of each device.

15. A charged particle-optical apparatus for testing an array of devices each having an electrical connection between two electrodes controllable by a signal applied to a control element, the charged particle-optical apparatus comprising:
a reference voltage supply configured to supply a reference electric potential to a first electrode of the two electrodes of each device;
a charged particle-optical device configured to direct a charged particle beam onto a second electrode of the two electrodes of each device;
a signal supply configured to vary a signal applied to the control element of each device; and
a detector for monitoring, for each signal applied, signal charged particles from the second electrode of each device.

16. The charged particle-optical apparatus of claim 15, further comprising a substrate at a sample location, the substrate comprising an array of devices each having an electrical connection between two electrodes controllable by a signal applied to a control element.

17. The charged particle-optical apparatus of claim 16, wherein the devices are logic transistors or DRAM structures.

18. The charged particle-optical apparatus of claim 16, wherein at least one structural feature of the devices varies in a predetermined way across the array.

19. The charged particle-optical apparatus of claim 18, wherein the at least one feature comprises at least one of an overlay shift between layers of the device and a dimension of a component of the device.

20. A non-transitory computer readable medium that stores instructions that are executable by one or more processors of a device to cause the device to perform operations for testing an array of devices each having an electrical connection between two electrodes controllable by a signal applied to a control element, the operations comprising:
controlling application of a reference electric potential to a first electrode of the two electrodes of each device;
controlling direction of a charged particle beam onto a second electrode of the two electrodes of each device;
controlling variation of a signal applied to the control element of each device; and
controlling monitoring, for each signal applied, of signal charged particles from the second electrode of each device.
